(19) United States
(12) Patent Application Publication
(10) Pub. No.: US 2020/0228034 A1
(43) Pub. Date: Jul. 16, 2020

(54) METHOD AND DEVICE FOR ESTIMATING THE TORQUE RIPPLE OF AN ELECTRIC MOTOR

(71) Applicant: AVL LIST GMBH, GRAZ (AT)

(72) Inventors: HELMUT KOKAL, GRAZ (AT); LUIGI GIORDANO, HART BEI GRAZ (AT); MARIO PROPST, OBDACH (AT)

(21) Appl. No.: 16/632,681

(22) PCT Filed: Jul. 20, 2018
(86) PCT No.: PCT/EP2018/069703

§ 371 Date: Jan. 21, 2020

(30) Foreign Application Priority Data
Jul. 21, 2017 (AT) A 50613/2017

(51) Int. Cl. H02P 6/10; G01M 13/025; G01R 31/34; H02P 23/14

(52) U.S. Cl. CPC H02P 6/10; G01M 13/025; H02P 2101/45; H02P 23/14; G01R 31/34

(57) ABSTRACT

A method and a device for estimating the torque ripple T_{TR} of an electric motor connected to a load. An ideal rotational speed ω_{ideal} of the electric motor is determined from an actuating torque T_{set_UUT} for the electric motor. An output torque T_{shaft} is measured at the load and a moment of mass inertia J of the electric motor in the controlled system of a control circuit. The ideal rotational speed ω_{ideal} is adjusted by a controller of the control circuit on the basis of the real rotational speed ω_{UUT} measured at the electric motor in such a way that the current torque ripple T_{TR} is generated as a manipulated variable of the controller.

The invention relates to a method and a device for estimating the torque ripple of an electric motor.

Electric motors, in particular permanent magnet synchronous motors (PMSM), are widely used in the automotive sector. These electric motors are usually used in combination with a transmission and drive shafts to the drive wheels as a drivetrain. Such a drivetrain represents a complex mechanical system with structural and torsional eigenmodes. The occurrence of periodic excitations in the frequencies close to the frequencies of these eigenmodes may cause noises that are unpleasant for the driver. They may however also have effects on the lifetime of components, to the extent that individual components of the drivetrain are destroyed.

A typical side-effect of the use of such electric motors is the occurrence of a torque ripple, which is also known by the term “ripple moment”. This is understood as meaning a slightly rotary-angle-dependent torque distribution over the rotary angle of the rotor of the electric motor. Causes may be an uneven distribution of the motor winding, inhomogeneities of the permanent magnets, but also asymmetries of the components used in the electronics.

Typically, these torque ripples occur in orders of the rotational frequency, the order number being determined for example by the number of pairs of poles and the number of slots.

Another typical side-effect is the occurrence of so-called cogging torques in the case of such motors. Cogging torque is the term used for the torque ripple of the deenergized electric motor.

In order to be able to measure exactly the torque ripple occurring, a measurement of the torque at the output shaft of the electric motor is of advantage. Usually, however, no torque measurement is provided in the electric motor/transmission assembly, or is technically difficult to realize.

Using a test bench on which the output torque of the electric motor is measured, for example by means of a measuring flange, the torque ripple can also be calculated in a post-processing step. For this purpose, however, it is required to measure and differentiate the rotational speed of the electric motor. This is problematic during operation, and is usually only possible by low-pass filtering of the measurement signal, which is complex and highly susceptible to errors.

One of the objects of the invention is therefore to provide a method and a device by which torque ripples of an electric motor can be estimated as exactly as possible on a test bench and during operation.

This and other objects are achieved according to the invention by a method according to patent claim 1. The method according to the invention estimates the torque ripple T_{TR} of an electric motor connected to a load from an actuating torque T_{set_UUT} for the electric motor, an output torque T_{shaft} measured at the load and the known moment of mass inertia J of the electric motor, in that a control circuit for adjusting the rotational speed of the electric motor is formed. In the controlled system of the control circuit, the ideal rotational speed ω_{ideal} of the electric motor is determined and this ideal rotational speed ω_{ideal} is adjusted by the controller of the control circuit on the basis of the real rotational speed ω_{UUT} measured at the electric motor in such a way that the current torque ripple T_{TR} appears as a manipulated variable at the output of the controller. The manipulated variable can then be led to the outside and picked off.

The controller may be designed in particular as a PI controller. The method according to the invention may be used for estimating the torque ripple of a permanent magnet synchronous machine. The method may be advantageously used both on a test bench and directly in a vehicle. The load may be a controllable load. The method may also be used during the operation of a vehicle driven by the electric motor, as long as the measured variables of the rotational speed and the shaft torque are known. This is advantageous because it means that the estimate of the torque ripple can be performed in real time and a complex post-processing step is not necessary. Furthermore, differentiation of the measured motor speed is not necessary.

The invention also extends to a device for estimating the torque ripple T_{TR} of an electric motor connected to a load via a shaft. The device according to the invention comprises a sensor for measuring the real rotational speed ω_{UUT} of the electric motor and a sensor for measuring the output torque T_{shaft} of the load.

The device also comprises a control circuit for adjusting the rotational speed of the electric motor, comprising a controlled system and a controller. In the controlled system, an ideal rotational speed ω_{ideal} of the electric motor is determined from an actuating torque T_{set_UUT} of the electric motor, the output torque T_{shaft} and a moment of mass inertia J of the electric motor. The controller is designed in such a way that it adjusts the ideal rotational speed ω_{ideal} on the basis of the real rotational speed ω_{UUT} in such a way that the torque ripple T_{TR} is generated as a manipulated variable of the controller. This manipulated variable can then be led to the outside and picked off.

According to the invention, it may be provided that the device is part of a test bench for an electric motor. According to the invention, it may be provided that the electric motor is a permanent magnet synchronous machine, an asynchronous machine or a reluctance motor. The load may be a controllable load. The device may, however, also be part of the drive of a vehicle.

Further features according to the invention are provided by the patent claims, the description of the embodiment examples and the drawings.

The invention is explained in more detail below on the basis of an exemplary embodiment example. In the drawing:

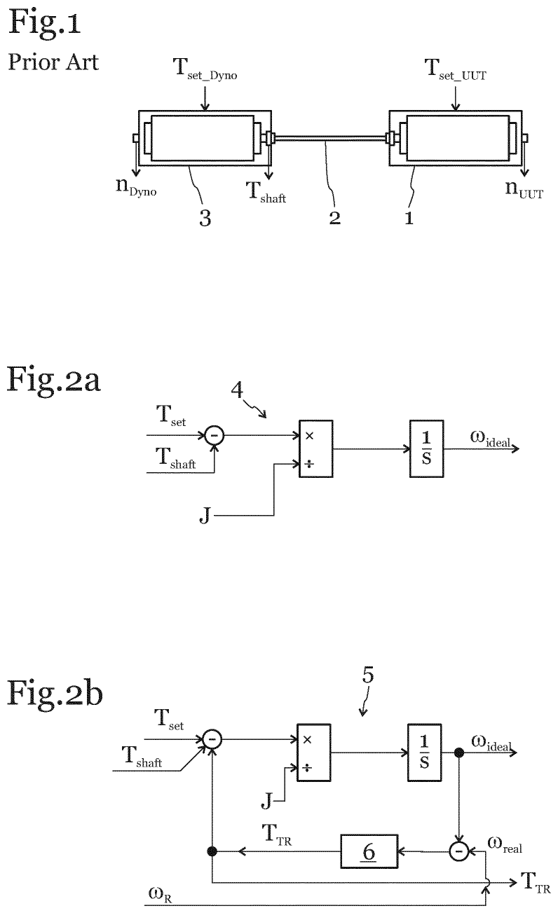

FIG. 1 shows a conventional setup of a test bench for an electric motor;

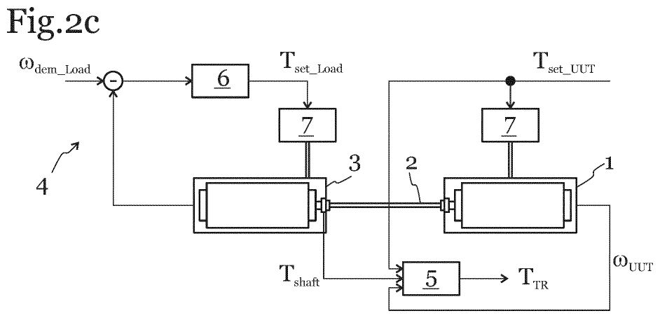

FIG. 2a-2c: show details of an embodiment of the system and method according to the invention.

FIG. 1 shows a conventional setup of a test bench for an electric motor 1. The electric motor 1 to be tested (test piece or Unit-Under-Test UUT) is connected to a controllable load 3 via a shaft 2. With a control unit 4 (not represented in this figure) of the load 3, various loading states are preset for the electric motor 1 to be tested, for example a presetting of the rotational speed to be achieved or the torque to be achieved. Such test benches are generally used without a transmission, drivetrain and other drive components.

In this figure, T_{set_UUT} denotes the actuating torque and n_{UUT} denotes the measured rotational speed at the electric motor 1 to be tested. The symbol T_{shaft} denotes the output torque measured at the shaft 2. The rotational speed preset at the load 3 is denoted by the symbol T_{set_Dyno}, and the rotational speed measured at the load 3 is denoted by the symbol n_{Dyno}.

The rotational speed measured at the test piece can be used to perform a calculation of the torque ripple (ripple moment) T_{TR} in a post-processing step, the previously determined moment of mass inertia J_{UUT} of the electric motor 1 being used for this purpose:

$${T}_{TR} = {J}_{UUT} ( {\dot{n}}_{UUT} \frac{π}{30} ) - {T}_{{set}_{UUT}} + {T}_{shaft}$$

However, a differentiation of the measured rotational speed n_{UUT} while operation is in progress is problematic and is usually only meaningfully possible with low-pass filtering of the signal.

FIG. 2a shows an ideal torque generator 4, which can be used as part of the method according to the invention. In this ideal torque generator 4, Tₛₑₜ denotes the actuating torque, T_{shaft} denotes the measured output torque, and ω_{ideal} denotes the rotational speed of the ideal electric motor. The moment of mass inertia of the electric motor is denoted by the symbol J. The mathematical relationship is as follows:

$${ω}_{ideal} = \frac{1}{J} \int ( {T}_{set} - {T}_{shaft} )$$

For the calculation of the real rotational speed ωᵣₑₐₗ, added to the actuating torque and the output torque is the unknown torque ripple (ripple moment) T_{TR}:

$${ω}_{real} = \frac{1}{J} \int ( {T}_{set} - {T}_{shaft} + {T}_{TR} )$$

Consequently, the ideal rotational speed ω_{ideal} is equal to the real rotational speed ωᵣₑₐₗ if, in addition to the actuating torque and the output torque, the ripple moment T_{TR} is taken into account at the input of the ideal electric motor.

FIG. 2b shows a correspondingly designed control circuit 5, in which the ideal rotational speed ω_{ideal} is adjusted as a controlled variable on the basis of the real measured rotational speed ωᵣₑₐₗ as a reference variable. Provided for this purpose is a controller 6, which in the present embodiment example is designed as a PI controller. The controller 6 is fed the difference between the ideal rotational speed ω_{ideal} and the real rotational speed ωᵣₑₐₗ as a system deviation.

The controller 6 produces a torque deviation as a manipulated variable. In the controlled system, the current actuating torque Tₛₑₜ and the measured output torque T_{shaft} are subtracted from the manipulated variable, and the result is divided by the moment of mass inertia J and the time derivative is formed, so that the current rotational speed is formed as the controlled variable.

The output variable of the controller 6 consequently corresponds to the current torque ripple, that is to say the ripple moment T_{TR}. The current torque ripple at a given time is consequently automatically obtained in this control circuit 5 as a byproduct of the speed control carried out.

FIG. 2c shows an embodiment of the invention in the example of a specific test bench. Once again, the electric motor 1 to be tested is connected to a controllable load 3 via a shaft 2. In this figure, T_{set_UUT} again denotes the actuating torque of the electric motor 1 to be tested and ω_{UUT} denotes the measured rotational speed at the electric motor 1 to be tested.

The controller 6 calculates from the difference of the rotational speed of the load 3 and the preset rotational speed ω_{dem_Load} the setpoint torque T_{set_Load} of the load 3.

Both the load 3 and the electric motor 1 to be tested 1 are activated by means of a driver unit 7, which converts the desired torque T_{set_Load} and T_{set_UUT} into corresponding activation signals for the load 3 and the electric motor 1, respectively. The symbol T_{shaft} again denotes the output torque measured at the shaft 2.

As explained in connection with FIG. 2b, the current ripple moment T_{TR} is determined in the control circuit 5 from T_{set_UUT}, T_{shaft} and the measured rotational speed ω_{UUT}, without a differentiation of the current rotational speed of the electric motor being required.

The invention is not restricted to a specific design of the electric motor, the load or the control circuit, but comprises all methods and devices within the scope of the following patent claims.

1-11. (canceled)

12. A method for estimating a torque ripple T_{TR} of an electric motor connected to a load, the method comprising:
determining an ideal rotational speed ω_{ideal} of the electric motor from an actuating torque T_{set_UUT} for the electric motor, an output torque T_{shaft} measured at the load, and a moment of mass inertia J of the electric motor in a controlled system of a control circuit; and
adjusting the ideal rotational speed ω_{ideal} by a controller of the control circuit on a basis of a real rotational speed ω_{UUT} measured at the electric motor to thereby generate a current torque ripple T_{TR} as a manipulated variable of the controller.

13. The method according to claim 12, which comprises estimating the torque ripple of a permanent magnet synchronous machine.

14. The method according to claim 12, which comprises carrying out the method on a test bench.

15. The method according to claim 12, wherein the load is a controllable load.

16. The method according to claim 12, which comprises carrying out the method during an operation of a vehicle driven by the electric motor.

17. The method according to claim 12, which further comprises compensating for the torque ripple.

18. A device for estimating the torque ripple T_{TR} of an electric motor connected to a load, the device comprising:
a sensor for measuring a real rotational speed ω_{UUT} of the electric motor;
a sensor for measuring an output torque T_{shaft} of the load;
wherein
a control circuit with:
a controlled system configured to determine an ideal rotational speed ω_{ideal} of the electric motor from an actuating torque T_{set_UUT} of the electric motor, the output torque T_{shaft}, and a moment of mass inertia J of the electric motor; and
a controller configured to adjust the ideal rotational speed ω_{ideal} on a basis of the real rotational speed ω_{UUT} in such a way that the torque ripple T_{TR} is generated as a manipulated variable of the controller.

19. The device according to claim 18, constituting a part of a test bench for an electric motor.

20. The device according to claim 18, wherein the load is a controllable load.

21. The device according to claim 18, constituting a part of a drive of a vehicle.

22. The device according to claim 18, wherein the electric motor is a permanent magnet synchronous machine.
